(19) United States
(12) Patent Application Publication
(10) Pub. No.: US 2013/0342118 A1
(43) Pub. Date: Dec. 26, 2013

(54) LED Backlight Driving Circuit, LCD Device, and Manufacturing Method

(71) Applicants: Xianming Zhang, Shenzhen (CN); Yuhua Chang, Shenzhen (CN); Mingwei Chen, Shenzhen (CN)

(72) Inventors: Xianming Zhang, Shenzhen (CN); Yuhua Chang, Shenzhen (CN); Mingwei Chen, Shenzhen (CN)

(21) Appl. No.: 13/574,448

(22) PCT Filed: Jun. 26, 2012
(86) PCT No.: PCT/CN2012/077500

§ 371 Date: Jul. 20, 2012

(30) Foreign Application Priority Data
Jun. 21, 2012 (CN) 201210207895.7

(51) Int. Cl. H05B 37/00; H05K 13/00

(52) U.S. Cl. 315/192; 29/825

(57) ABSTRACT

The invention provides an LED backlight driving circuit, an LCD device, and a manufacturing method. The LED backlight driving circuit includes at least two lightbars arranged in parallel connection; at least one LED lightbar is in series connection with a divider resistor(s) used for balancing the voltage difference between the LED lightbars. In the invention, because the LED lightbar(s) is in series connection with the divider resistors used for balancing the voltage difference between the LED lightbars, the divider resistors with different resistance can be connected in series according to different resistance of all the LED lightbars during design, to enable the total voltage difference of each LED lightbar and the divider resistor to be equal; thus, the voltages of all the pins of the IC coupled into the drive converter can be consistent, and no additional current can be generated in the IC because no voltage differences exist between pins basically; thus, the power consumption of the IC is reduced, and the heat productivity of the IC is reduced, thereby reducing the temperature of the IC.

### TECHNICAL FIELD

The invention relates to the field of liquid crystal displays (LCDs), and more particularly to a light emitting diode (LED) backlight driving circuit, an LCD device, and a manufacturing method.

### BACKGROUND

LCD devices include LCD panels, and backlight modules. In a backlight module employing LED(s), if a plurality of LED lightbars are used, as shown in FIG. 1 and FIG. 2, the LED lightbars are arranged in parallel connection, each LED lightbar is in series connection to the same converter, a control integrated circuit (IC) is arranged in the converter, the IC is coupled with the output end of each LED lightbar by a connector, and an isolating switch Q1 is in series connection between the IC and the connector. Because the voltages of all the LED lightbars are different, namely V_{F1}, V_{F2}, V_{F3} and V_{F4} are unequal, and the voltages of the branch V_{LED} of the whole LED lightbar are equal, the inequality of V_{F1}, V_{F2}, V_{F3} and V_{F4} results in different voltages of V_{LED1}, V_{LED2}, V_{LED3} and V_{LED4} applied onto the IC of the converter. Current is generated when voltage differences exist, thereby increasing the temperature of the IC used in the backlight drive converter. To solve the temperature problem, a thermal pad or bare copper is required to be added, thereby increasing the cost.

### SUMMARY

In view of the above-described problems, the aim of the invention is to provide an LED backlight driving circuit, an LCD device, and a manufacturing method thereof capable of reducing the temperature of the IC of the backlight drive converter.

The aim of the invention is achieved by the following technical scheme.

An LED backlight driving circuit comprises at least two lightbars arranged in parallel connection; at least one LED lightbar is in series connection with a divider resistor(s) used for balancing the voltage difference between the LED lightbars.

Preferably, the divider resistors are fixed resistors with fixed resistance. The fixed resistors have the advantages of low cost and favor the reduction of the cost of raw materials.

Preferably, except the LED lightbar with maximum voltage difference, the rest LED lightbars are in series connection with the fixed resistors. By taking the voltage of the LED lightbar with maximum voltage difference as a reference voltage, on the one hand, the resistor of one LED lightbar is saved; on the other hand, because the reference voltage is low, the rest LED lightbars are in series connection with resistors with low resistance. Thus, the consumption of electric energy on the resistors is reduced, thereby favoring the reduction of energy consumption.

Preferably, the fixed resister(s) is in series connection between the LED lightbar(s) and an isolating switch. By adding the isolating switch, when the LED lightbar(s) is short-circuited, the isolating switch is disconnected, thereby preventing all the branch voltages from being applied onto the IC and then damaging the IC.

An LCD device comprises an LED backlight driving circuit. The LED backlight driving circuit comprises at least two lightbars arranged in parallel connection; at least one LED lightbar is in series connection with a divider resistor(s) used for balancing the voltage difference between the LED lightbars, and the divider resistors are fixed resisters with fixed resistance.

Preferably, except the LED lightbar with maximum voltage difference, the rest LED lightbars are in series connection with the fixed resistors. By taking the voltage of the LED lightbar with maximum voltage difference as a reference voltage, on the one hand, the resistor of one LED lightbar is saved; on the other hand, because the reference voltage is low, the rest LED lightbars are in series connection with the resistors with low resistance. Thus, the consumption of electric energy on the resistors is reduced, thereby favoring the reduction of energy consumption.

Preferably, the fixed resistor(s) is in series connection between the LED lightbar(s) and an isolating switch. By adding the isolating switch, when the LED lightbar(s) is short-circuited, the isolating switch is disconnected, thereby preventing all the branch voltages from being applied onto the IC and then damaging the IC.

A manufacturing method of the LED backlight driving circuit comprises a step A: connecting the divider resistor(s) used for balancing the voltage difference between the LED lightbars in the branch circuit of the LED lightbar in series, to enable the voltage difference between the LED lightbars to be consistent.

Preferably, the step A comprises:

A1: Calculating the voltage difference of the two ends of each LED lightbar, and taking the maximum voltage difference as a reference voltage; and

A2: Connecting all the branches of the rest LED lightbars with the fixed resistors with fixed resistance as divider resistors in series except the LED lightbar which is consistent with the reference voltage, so that the sum of the voltage differences of the LED lightbar and the fixed resistor is equal to the reference voltage.

By taking the voltage of the LED lightbar with maximum voltage difference as a reference voltage, on the one hand, the resistor of one LED lightbar is saved; on the other hand, because the reference voltage is low, the rest LED lightbars are in series connection with the resistors with low resistance. Thus, the consumption of electric energy on the resistors is reduced, thereby favoring the reduction of energy consumption.

Preferably, in the step A, each LED lightbar is in series connection with an isolating switch, and the divider resistor is in series connection between the LED lightbar and the isolating switch. By adding the isolating switch, when the LED lightbar(s) is short-circuited, the isolating switch is disconnected, thereby preventing all the branch voltages from being applied onto the IC and then damaging the IC.

In the invention, because the LED lightbar(s) is in series connection with divider resistor(s) used for balancing the voltage difference between the LED lightbars, the divider resistors with different resistance can be connected in series according to different resistance of each LED lightbars during design, to enable the total voltage difference of each LED lightbar and the divider resistor to be equal; thus, the voltages of all the pins of the IC coupled into the drive converter can be consistent, and no additional current can be generated because no voltage differences exist between pins basically; thus, the power consumption of the IC is reduced, and the heat productivity of the IC is reduced, thereby reducing the temperature of the IC.

### BRIEF DESCRIPTION OF FIGURES

FIG. 1 is a schematic diagram of a conventional LED backlight driving circuit;

FIG. 2 is a schematic diagram of an LED backlight driving circuit with an isolating switch;

FIG. 3 is a schematic diagram of an LED backlight driving circuit of a first example of the invention;

FIG. 4 is a schematic diagram of an LED backlight driving circuit of a second example of the invention;

FIG. 5 is a schematic diagram of an LED backlight driving circuit with an isolating switch of a second example of the invention;

FIG. 6 is a schematic diagram of an LED backlight driving circuit of a third example of the invention; and

FIG. 7 is a schematic diagram of an LED backlight driving circuit with an isolating switch of a third example of the invention.

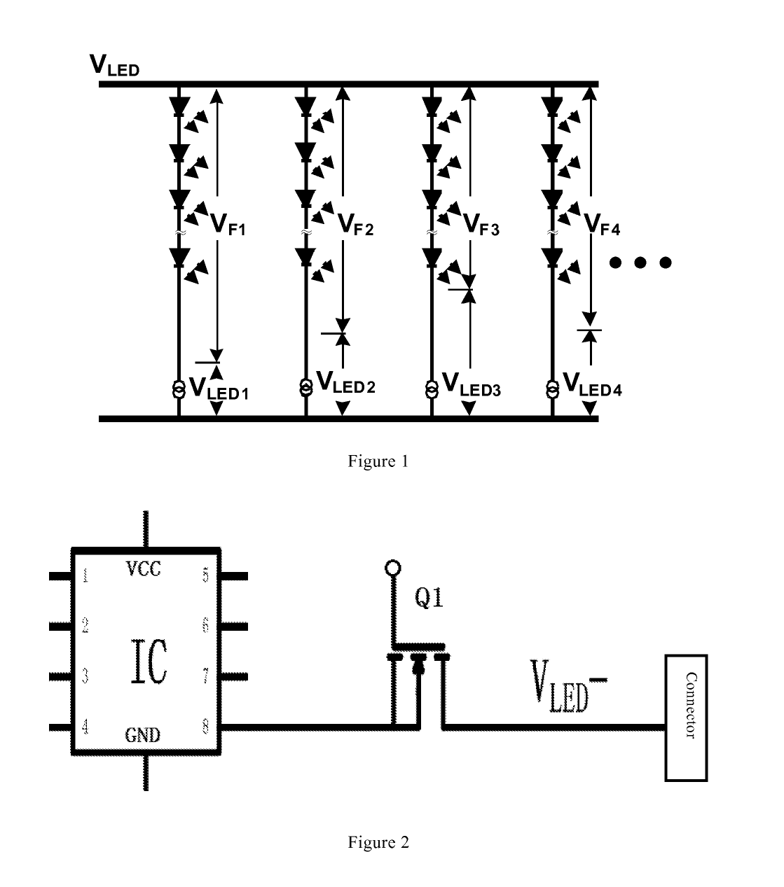

### DETAILED DESCRIPTION

An LCD device comprises a backlight module. The backlight module is provided with an LED backlight driving circuit. The LED backlight driving circuit comprises at least two LED lightbars arranged in parallel connection; at least one LED lightbar is in series connection with a divider resistor used for balancing the voltage difference between the LED lightbars.

In the invention, because the LED lightbar(s) is in series connection with divider resistor(s) used for balancing the voltage difference between the LED lightbars, the divider resistors with different resistance can be connected in series according to different resistance of all the LED lightbars during design; thus, the total voltage difference of each LED lightbar and the divider resistor is equal; therefore, the voltages of all the pins of the IC coupled into the drive converter can be consistent, and no additional current can be generated because no voltage differences exist between pins basically; thus, the power consumption of the IC is reduced, and the heat productivity of the IC is reduced, thereby reducing the temperature of the IC. The LED backlight driving circuit of the invention will be further described in accordance with the Figures and preferred examples.

### EXAMPLE 1

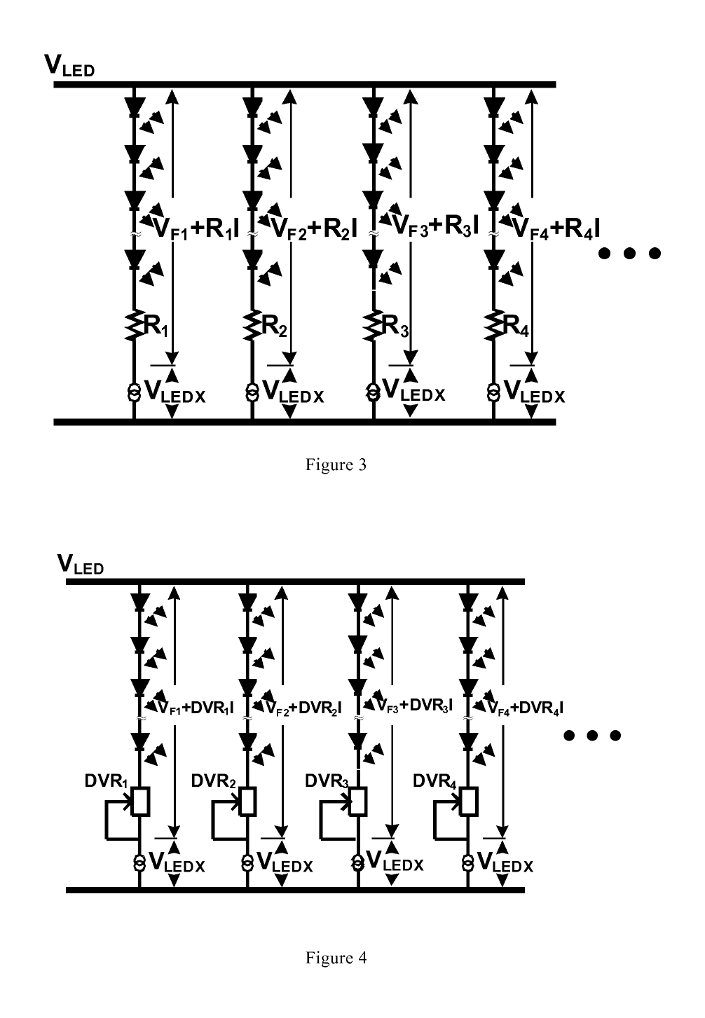

In the example, the divider resistors are fixed resistors with fixed resistance. As shown in FIG. 3, except the LED lightbar with maximum voltage difference, the rest LED lightbars are in series connection with the fixed resistors with fixed resistance used for balancing the voltage difference between the LED lightbars. By taking the voltage of the LED lightbar with maximum voltage difference as a reference voltage, on the one hand, the resistor of one LED lightbar is saved; on the other hand, because the reference voltage is low, the rest LED lightbars are in series connection with the resistors with low resistance. Thus, the consumption of electric energy on the resistors is reduced, thereby favoring the reduction of energy consumption.

Furthermore, in the LED backlight driving circuit, the output end of each LED lightbar is coupled with an isolating switch, and the fixed resistor is in series connection between the LED lightbar and the isolating switch. By adding the isolating switch, when the LED lightbar is short-circuited, the isolating switch is disconnected, thereby preventing all the branch voltages from being applied onto the IC and then damaging the control IC.

The invention further provides a manufacturing method of the LED backlight driving circuit. We can measure the V_{F1}, V_{F2}, V_{F3}, V_{F4} . . . of all the LED lightbars under the required current I after manufacturing each LED lightbar. Thus, the LED lightbar with maximum voltage is measured, and the voltage thereof is set to be V_{FX}. Thus, we can connect each of the rest LED lightbars with a fixed resistor in series, wherein R₁=(V_{FX}−V_{F1})/I, R₂=(V_{FX}−V_{F2})/I . . . R_{N}=(V_{FX}−V_{FN})/I and so on.

Therefore, by connecting each LED lightbar with a different resistor in series, the voltages of all the branches of each LED lightbar are consistent, namely V_{F1}+R₁I=V_{F2}+R₂I=V_{F3}+R₃I=V_{F4}+R₄I= . . . =V_{FX}. Thus, the voltage difference between the LED lightbars is basically eliminated, so that the V_{LEDX} at the IC side keep consistent.

By taking the voltage of the LED lightbar with maximum voltage difference as a reference voltage, on the one hand, the resistor of one LED lightbar is saved; on the other hand, because the reference voltage is low, the rest LED lightbars are in series connection with resistors with low resistance. Thus, the consumption of electric energy on the resistors is reduced, thereby favoring the reduction of energy consumption.

### EXAMPLE 2

In the example, the divider resistors are digital potentiometers of which the resistance is adjusted by electric signals. As shown in FIG. 4, there are four LED lightbars in the Figure. Each digital potentiometer is connected with one LED lightbar, i.e. DVR₁-DVR₄ respectively. Thus, the resistance of the branch of each LED lightbar is adjustable. Furthermore, except the LED lightbar with maximum voltage difference, the rest LED lightbars are in series connection with the digital potentiometers of which the resistance is adjusted by electric signals. By taking the voltage of the LED lightbar with maximum voltage difference as a reference voltage, on the one hand, the resistor of one LED lightbar is saved; on the other hand, because the reference voltage is low, the rest LED lightbars are in series connection with resistors with low resistance. Thus, the consumption of electric energy on the resistors is reduced, thereby favoring the reduction of energy consumption.

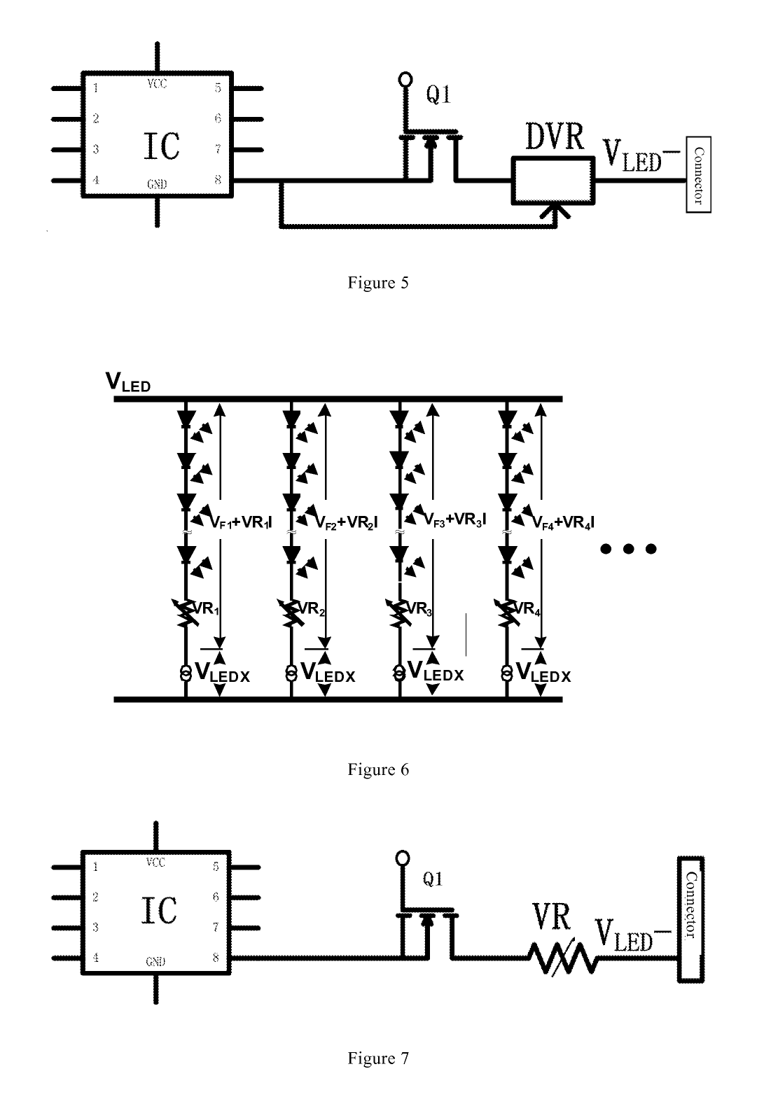

Furthermore, as shown in FIG. 5, the branch of each LED lightbar is further in series connection with an isolating switch Q1, and a connector. One end of the digital potentiometer DVR is coupled to the IC in series by the isolating switch Q1, and the other end is coupled to the output end of the LED lightbar by the connector. By adding the isolating switch, when the LED lightbar is short-circuited, the isolating switch is disconnected, thereby preventing all the branch voltages from being applied onto the IC and then damaging the IC. The connector facilitates overhaul.

The example further provides a manufacturing method of the LED backlight driving circuit. We can measure the V_{F1}, V_{F2}, V_{F3}, V_{F4} . . . of all the LED lightbars under the required current I after manufacturing each LED lightbar. Thus, the LED lightbar with maximum voltage is measured, and the voltage thereof is set to be V_{FX}. Thus, we can connect each of the rest LED lightbars with a digital potentiometer in series, and dynamically adjust the resistance of the digital potentiometers by electric signals. Therefore, V_{F1}+DVR₁=V_{F2}+DVR₂=V_{F3}+DVR₃=V_{F4}+DVR₄= . . . =V_{FX}. Under the condition of the total voltage V_{LED}, is constant, the total voltage of each the LED lightbar and the digital resistor keeps consistent, and then the voltage difference between the pins of the IC is low, namely V_{LEDX} keeps consistent and approaches most closely to the required voltage of the IC, thereby reducing the heat productivity of the IC.

With the temperature rise of the LED lightbars during use, the resistance will be changed. In the example, by using the digital potentiometers, the resistance can be automatically adjusted by a digital command mode at any time during use; thus, the total voltage of each LED lightbar and the digital potentiometer connected with the LED lightbar in series can keep consistent, thereby effectively reducing the heat productivity of the IC.

### EXAMPLE 3

In the example, the divider resistors are variable resistors with adjustable resistance. As shown in FIG. 6, there are four LED lightbars in the Figure. Each variable resistor is connected with one LED lightbar, i.e. VR₁-VR₄ respectively. Thus, the resistance of all the branches of each LED lightbar is adjustable. Furthermore, except the LED lightbar with the maximum difference voltage, the rest LED lightbars are in series connection with the variable resistors with adjustable resistance. By taking the voltage of the LED lightbar with maximum voltage difference as a reference voltage, on the one hand, the resistor of one LED lightbar is saved; on the other hand, because the reference voltage is low, the rest LED lightbars are in series connection with resistors with low resistance. Thus, the consumption of electric energy on the resistors is reduced, thereby favoring the reduction of energy consumption.

Furthermore, as shown in FIG. 7, the branch of each LED lightbar is further in series connection with an isolating switch Q1, and a connector. One end of the variable resistor VR is coupled to the IC in series connection by the isolating switch Q1, and the other end is coupled to the output end of the LED lightbar in series connection by the connector. By adding the isolating switch, when the LED lightbar is short-circuited, the isolating switch is disconnected, thereby preventing all the branch voltages from being applied onto the IC and then damaging the IC. The connector facilitates the overhaul of the circuit.

The invention further provides a manufacturing method of the LED backlight driving circuit. We can measure the V_{F1}, V_{F2}, V_{F3}, V_{F4} . . . of all the LED lightbars under the required current I after manufacturing each LED lightbar. Thus, the LED lightbar with maximum voltage is measured, and the voltage thereof is set to be V_{FX}. Thus, we can connect each of the rest LED lightbars with a variable resistor in series, and manually or mechanically adjust the resistance of the variable resistors. Thereof, V_{F1}+VR₁=V_{F2}+VR₂=V_{F3}+VR₃=V_{F4}+VR₄= . . . =V_{FX}. Under the condition that the total voltage V_{LED} is constant, the voltage of the LED lightbar is consistent with the total voltages of the digital resistors, and then the voltage difference between the pins of the control chip of the converter module is low, namely V_{LEDX} keeps consistent and approaches most closely to the required voltage of the control chip, thereby reducing the heat productivity of the IC.

In the example, because the variable resistors with adjustable resistance are arranged in the variable current circuit connected in series with the LED lightbars, the resistance of the variable resistors can be adjusted according to the resistance of different LED lightbars before use, to enable the total voltage of each LED lightbar and the variable resistor connected with the LED lightbar in series can keep consistent.

The divider resistors of the invention can further be other resistors. The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. An LED backlight driving circuit, comprising: at least two lightbars arranged in parallel connection; at least one said LED lightbar is in series connection with a divider resistor(s) used for balancing the voltage difference between said LED lightbars.

2. The LED backlight driving circuit of claim 1, wherein said divider resistors are fixed resistors with fixed resistance.

3. The LED backlight driving circuit of claim 2, wherein except the LED lightbar with maximum difference voltage, the rest LED lightbars are in series connection with said fixed resistors.

4. The LED backlight driving circuit of claim 2, wherein said the fixed resister(s) is in series connection between the LED lightbar(s) and an isolating switch.

5. An LCD device, comprising: an LED backlight driving circuit; wherein said LED backlight driving circuit comprises at least two lightbars arranged in parallel connection; at least one said LED lightbar is in series connection with a divider resistor(s) used for balancing the voltage difference between said LED lightbars, and said divider resistors are fixed resisters with fixed resistance.

6. The LCD device of claim 5, wherein except the LED lightbar with maximum voltage difference, the rest LED lightbars are in series connection with said fixed resistors.

7. The LCD device of claim 5, wherein said fixed resister(s) is in series connection between said LED lightbar(s) and an isolating switch.

8. A manufacturing method of the LED backlight driving circuit, comprising: a step A:
connecting said divider resistor(s) used for balancing the voltage difference between said LED lightbars in the branch of said LED lightbar in series, to enable the voltage difference between every two LED lightbars to be consistent.

9. The manufacturing method of the LED backlight driving circuit of claim 8, wherein said step A comprises:
A1: Calculating the voltage difference of the two ends of each LED lightbar, and taking the maximum voltage difference as a reference voltage;
A2: Connecting all the branches of the rest LED lightbars with fixed resistors with fixed resistance as divider resistors in series except the LED lightbar which is consistent with the reference voltage, so that the sum of the voltage differences of said LED lightbars and said fixed resistors is equal to said reference voltage.

10. The manufacturing method of the LED backlight driving circuit of claim 8, wherein in said step A, each LED lightbar is in series connection with an isolating switch, and said divider resistor(s) is in series connection between said LED lightbar and said isolating switch.
